(19) United States
(12) Patent Application Publication
(10) Pub. No.: US 2013/0153869 A1
(43) Pub. Date: Jun. 20, 2013

(54) CONDUCTIVE ELEMENTS IN ORGANIC ELECTRONIC DEVICES

(71) Applicants: Ricardo Mikalo, Heideblick (DE); Anja Wellner, Dresden (DE); Jens Dienelt, Radebeul (DE); Patrick Too, Cambridge (GB)

(72) Inventors: Ricardo Mikalo, Heideblick (DE); Anja Wellner, Dresden (DE); Jens Dienelt, Radebeul (DE); Patrick Too, Cambridge (GB)

(73) Assignee: PLASTIC LOGIC LIMITED, Cambridge (GB)

(21) Appl. No.: 13/701,571

(22) PCT Filed: Jun. 3, 2011
(86) PCT No.: PCT/EP11/59227

§ 371 Date: Feb. 15, 2013

(30) Foreign Application Priority Data
Jun. 4, 2010 (GB) 1009407.6

(51) Int. Cl. H01L 51/05; H01L 51/00

(52) U.S. Cl. CPC H01L 51/055; H01L 51/0021
USPC 257/40; 438/99

(57) ABSTRACT

A technique comprising: forming a conductive element of an electronic device on a portion of the surface of a first organic layer, applying a second organic layer over said conductive element and said first organic layer, and then treating at least one of the first and second organic layers to increase the strength of adhesion between said first and second organic layers. Thereby the retention of said conductive element on said first organic layer is improved.

The present invention relates to conductive elements in organic electronic devices. In one embodiment, it relates to conductive elements in organic thin-film transistors (TFTs).

There is an interest in using metals for the conductive elements in organic electronic devices because of their high conductivity and processability.

Gold and copper are two of a number of metals that have been identified as candidate materials for the conductive elements in organic electronic devices. The inventors have found by experiment that the use of gold for the gate-line in a thin-film transistor (TFT) device can reduce the number of gate breaks and improve the lifetime of the TFT device.

There has been identified the challenge of effectively integrating metal elements such as gold elements in an organic device structure.

It is an aim of the present invention to meet this challenge.

The present invention provides a method comprising: forming a conductive element of an electronic device on a portion of the surface of a first organic layer, applying a second organic layer over said conductive element and said first organic layer, and then treating at least one of the first and second organic layers to increase the strength of adhesion between said first and second organic layers and thereby improve the retention of said conductive element on said first organic layer.

In one embodiment, said conductive element is a metal element.

In one embodiment, forming said metal element includes patterning a deposit of metal through the direct absorption of laser energy and evaporation of metal at selected regions of said deposit.

In one embodiment, said metal is a noble metal element.

In one embodiment, said noble metal element is gold.

In one embodiment, the conductive element forms part of a conductive pattern, and wherein the density of coverage of the conductive pattern is no more than 90% for any 1 mm×1 mm unit area.

In one embodiment, the conductive element forms part of a conductive pattern, and wherein the density of coverage of the conductive pattern is no more than 50% for any 1 mm×1 mm unit area.

In one embodiment, the second organic layer exhibits better chemical barrier properties than the first organic layer.

The present invention also provides a method comprising: forming a gold metal element of an electronic device on an underlying organic layer, wherein the forming includes patterning a deposit of metal through the direct absorption of laser energy and evaporation of metal at selected regions of said deposit.

In one embodiment, said metal element is a gate line of a thin film transistor array and said underlying organic layer is located between said gate line and one or more semiconductor channels of said thin-film transistor array.

In one embodiment, the underlying organic layer comprises parylene.

In one embodiment, the method further comprises depositing the underlying organic layer by a vapour deposition technique.

In one embodiment, the method further comprises forming the metal deposit directly on the underlying organic layer without any intermediate layer for assisting the patterning of said deposit.

In one embodiment, said metal element is formed directly on said underlying organic layer without any intermediate layer for improving the adhesion between the metal element and the underlying organic layer.

The present invention further provides the use of a noble metal for a gate line in an organic thin-film transistor for the purpose of reducing gate-line breaks.

The present invention further provides the use of a noble metal for a gate line above a solution-processed organic gate dielectric layer having a thickness of no greater than about 300 nm.

The present invention further provides a method comprising: patterning a conductive layer by laser ablation of selected portions of said conductive layer; forming an electrically insulating layer over the patterned conductive layer, and forming a further conductive layer over the electrically insulating layer; wherein the electrically insulating layer has a thickness exceeding the height to which edges of said patterned metal layer are bent-up as a result of said patterning.

In one embodiment, the conductive layer defines gate lines of an array of transistors; the further conductive layer defines pixel electrodes of said array of transistors connected to respective drain electrodes below said conductive layer; and said electrically insulating layer has a thickness of at least 2 microns.

Hereunder, an embodiment of the present invention is described in detail herebelow, by way of example only, with reference to the accompany drawings, in which:

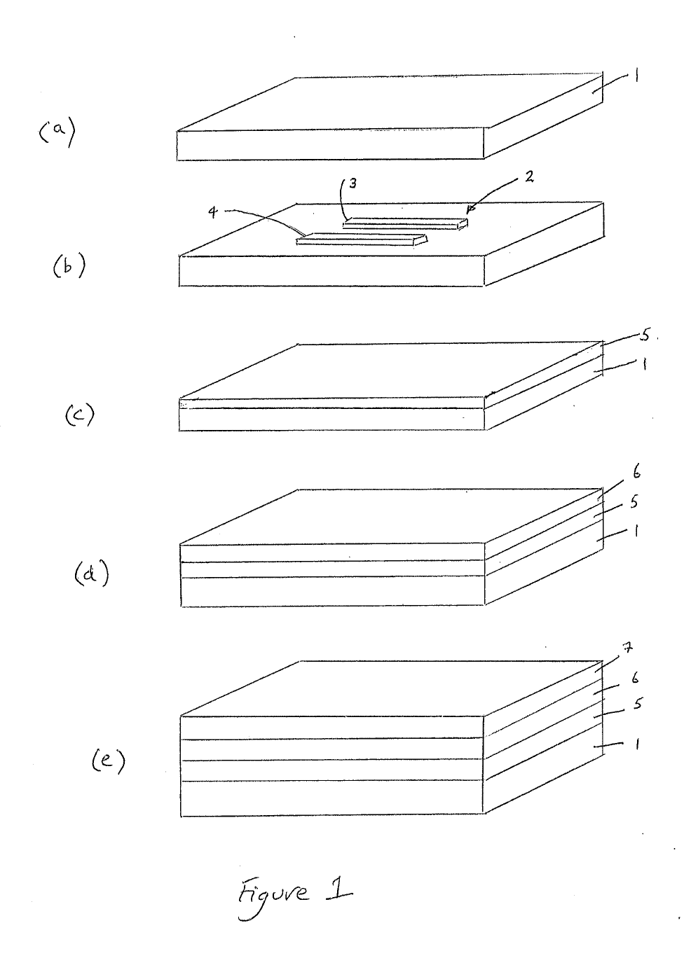

FIG. 1 illustrates a technique for incorporating a gold element into an organic electronic device according to an embodiment of the present invention;

FIG. 2 illustrates a technique for improving the retention of a large-area gold metal element on an organic layer in an organic electronic device in accordance with an embodiment of the present invention;

FIG. 3 illustrates an electrophoretic display device as an example of an electronic device to which the technique illustrated in FIG. 1 is applicable; and

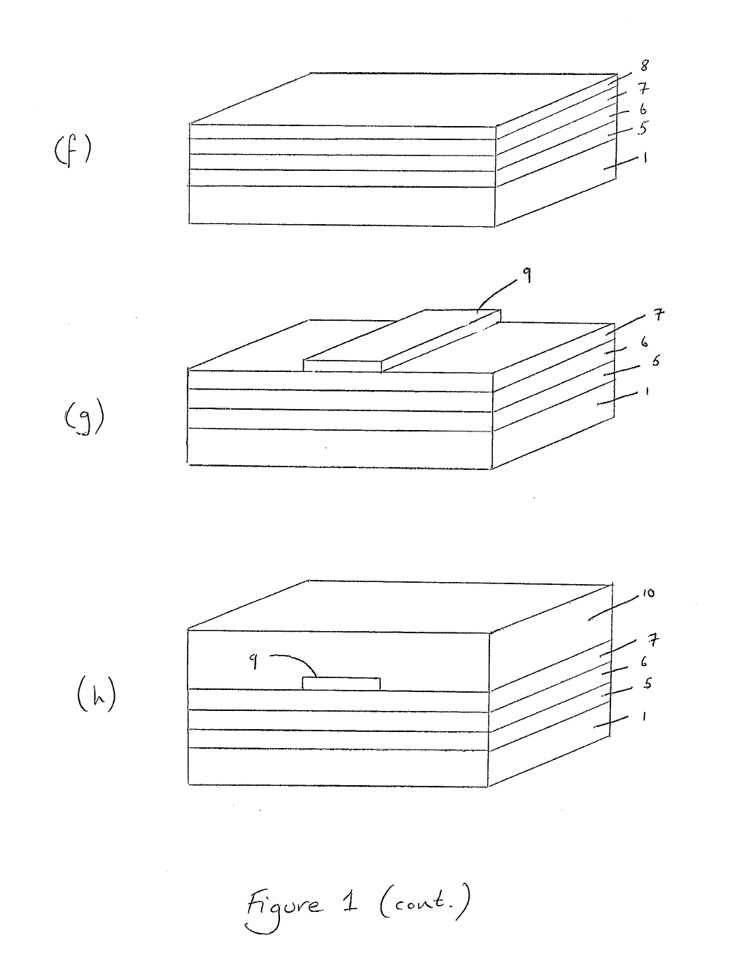

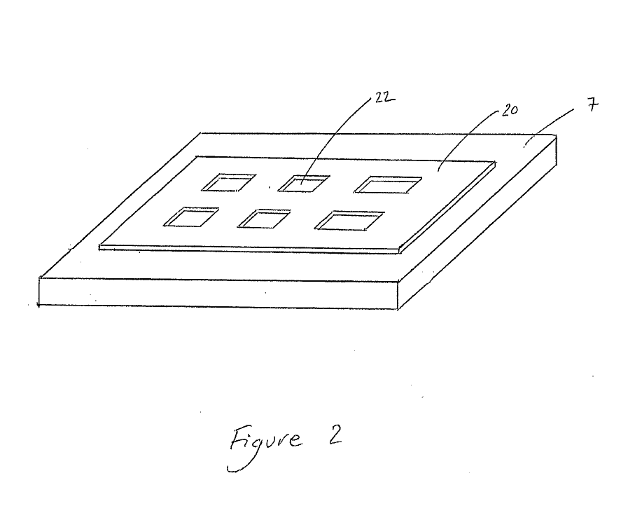

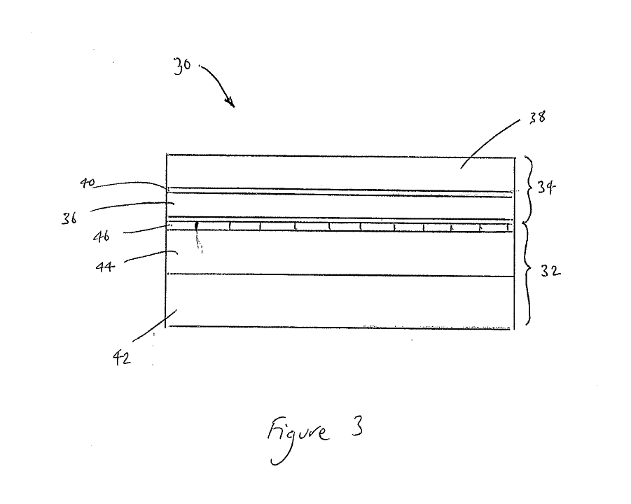

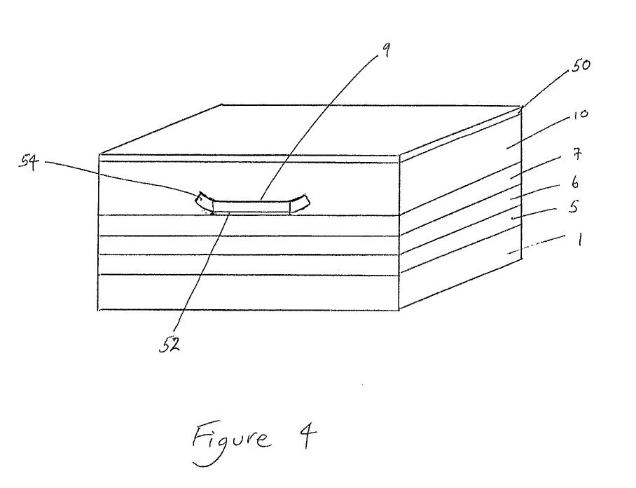

FIG. 4 illustrates a conductive layer patterning technique in accordance with an embodiment of the present invention.

A technique according to an embodiment of the present invention is described below for the example of producing a backplane 32 for an electrophoretic display device 30 of the kind illustrated in FIG. 3. The electrophoretic display device 30 comprises a front plane 34 including an electrophoretic display medium 36 supported on a plastic substrate 38 via a conductive layer 40 that functions as a reference voltage plane (COM plane), and a backplane 32 comprising a plastic substrate 42 supporting an array of TFTs 44 and associated pixel electrodes 46 for controlling the display medium.

FIG. 1 illustrates a technique in accordance an embodiment of the present invention for producing the TFT array of the backplane of an electrophoretic device of the kind illustrated in FIG. 3. Each of the steps illustrated in FIG. 1 are discussed below.

FIG. 1(b): a lower gold metal pattern 2 is formed on a support substrate 1 (such as a PET plastic substrate) by sputter deposition and photolithography. The metal pattern 2 defines the source and drain electrodes 3, 4 of an array of TFTs. Only the source and drain electrodes for a single TFT are shown in FIG. 1(b), but the gold metal pattern also defines the source and drain electrodes for other TFTs of the array, as well as lines for applying signal voltages to the source electrodes, and drain pads connected to the drain electrodes as feet for interconnect vias to pixel electrodes 46 at a higher level of the backplane 32. Examples of other techniques for producing a patterned conductive layer include: the direct-write printing of a solution-processible conducting material, such as a conducting polymer or the direct-write printing of a dispersion of metal nanoparticles or other metal precursor followed by annealing.

FIG. 1(c): organic semiconductor material is deposited from solution over the lower metal pattern 2 to form a semiconductor layer 5 defining the semiconductor channels of the array of TFTs, each semiconductor channel connecting the source and drain electrodes of the respective TFT. One example of a technique for depositing the organic semiconductor material from solution is by flexographic printing.

FIG. 1(d): an organic gate dielectric material is deposited from solution over the semiconductor layer 5 to form a gate dielectric layer 6. The gate dielectric layer 6 forms the active semiconductor—dielectric layer interface, which interface controls the field-effect mobility of the organic semiconductor, the amount of charge trapping and bias-stress degradation of the device. Examples of polymeric materials that can be used for a gate dielectric layer interfacing with a semiconductor layer in an organic TFT include: polymethylmethacrylate (PMMA), polyisobutylene (FIB), polyethylene, polypropylene, polystyrene (PS), poly-4-vinylphenol (PVP), polyethylene-co-propylene, and polyvinylalcohol (PVA) or copolymers thereof. One example of a technique for depositing the organic gate dielectric material from solution is by flexographic printing.

FIG. 1(e): a parylene material is deposited over the gate dielectric layer 6 by a thermal/chemical vapour deposition technique to form a parylene layer 7 having a thickness of between 10 and 10,000 nm, more particularly between 800 nm and 2000 nm. In more detail, a precursor of a parylene dimer is dissociated/cracked at high temperatures into a reactive monomer, and the reactive radicals react and form a parylene polymer (see below) at the surface of the gate dielectric layer 6. A flow of inert gas can be used to transport the reactive monomers to the surface of the gate dielectric layer 6. A number of different parylene derivatives are available, including (i) parylene with no substituents on the phenyl ring or aliphatic carbon atoms (Parylene N); (ii) parylene derivatives with substituents on the phenyl ring such as Parylene C with one substituent X═Cl on the phenyl ring and Parylene D with two X═Cl substituents on the phenyl ring.

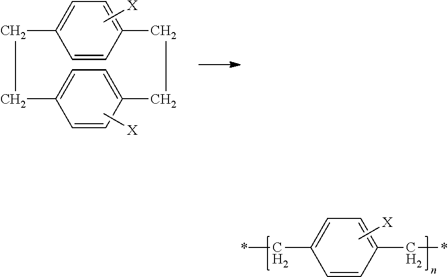

and (iii) parylene derivatives with substituents on the aliphatic carbon atoms such as Parylene AF illustrated below.

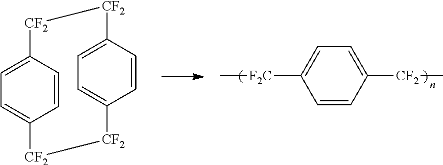

There are no catalysts or solvents required for this deposition process that could cause unnecessary stress on other components of the device. The vapour deposition process provides a completely pin-hole free and conformal parylene film 7, which has good dielectric properties, and reduces the risk of TFT failures caused by pinholes or other defects in the underlying gate dielectric layer 6 that may happen to arise as a result of defects on the surface of the support substrate 1, gate dielectric (6) or semiconductor layer (5). The dielectric layer 6 protects the semiconducting layer 5 during the thermal/chemical vapour deposition of the parylene layer 7. This beneficial effect has been observed for a broad range of polymer dielectrics, including gate dielectrics that have a similar dielectric constant to that of parylene. Without wanting to be bound by theory, it is thought that a possible explanation for this behaviour is that the first polymer gate dielectric acts to prevent semiconductor degradation that might occur when the highly reactive parylene radicals from the gas phase polymerize on the surface of the substrate.

It is also possible to omit the underlying gate dielectric layer and instead rely solely on the parylene layer as a gate dielectric layer between the semiconductor layer 5 and the gate lines 9 discussed below.

FIG. 1(f): a layer 8 of gold metal is deposited over the parylene layer 7 by a sputter deposition or evaporation technique.

FIG. 1(g): The gold layer 8 is patterned by laser ablation to form gate lines 9 which extend over a plurality of semiconductor channels of the array of TFTs. Only one gate line is shown in FIG. 1(g). The laser ablation is carried out using a laser beam at a frequency at which the gold metal directly absorbs the laser beam energy. Direct absorption of the laser beam energy by the gold layer in the irradiated regions causes rapid localised heating and evaporation in those regions. Another example of a technique for forming a patterned gold layer is by direct-write printing of a dispersion of inorganic nanoparticles of gold, followed by annealing. Other examples of techniques for forming a patterned conductive layer are photolithography or direct-write printing of a conducting polymer, such as polyethylenedioxythiophene doped with polystyrene sulfonic acid (PEDOT/PSS).

FIG. 1(h): SU-8 epoxy resin 10 is then deposited from solution over the patterned upper gold layer defining the gate lines 9 and the exposed portions of the parylene layer 7. A solvent is used that is compatible with the metal of the gate lines, i.e. does not react with the gate metal. An alternative technique for depositing a SU-8 epoxy resin layer is by laminating a pre-prepared dry film of SU-8 resin over the patterned upper gold layer defining the gate lines 9 and the exposed portions of the parylene layer 7. The resulting structure is then baked so as to promote intertwisting of the polymer chains making up the parylene and SU-8 epoxy resin layers 7 and 10 to thereby increase the strength of mechanical adhesion between the parylene and SU-8 epoxy resin layers. This increase in the strength of the mechanical adhesion between the parylene and SU-8 epoxy resin layers serves to improve the retention/fixing of the patterned upper gold layer (gate lines) 9 on the underlying parylene layer 7. The SU-8 epoxy resin layer has a thickness in the range of 2 to 6 microns, more particularly about 3.5 microns. Relatively high thicknesses are preferred from the point of view of avoiding gate line breaks because they allow the use of relatively high gate voltages; but relatively low thicknesses are preferred from the point of view of providing a good capacitance between the gate lines and overlying pixel electrodes (not shown).

Other examples of materials for use instead of the SU-8 epoxy resin layer include: parylene; polyethylene (PE); polypropylene (PP); polyvinylchloride (PVC); polystyrene (PS); polytetrafluorethylene (PTFE); polymethylmethacrylate (PMMA); PS-PMMA copolymers; polyisobutylenes; polynorborenes; polyamide; polyester; polycarbonate (PC); polyethyleneterephthalate (PET); Poly(methyl glutarimide) (PMGI); Phenol formaldehyde resin (DNQ/Novolac); polyethyleneglycol (PEG); and poly(organo)siloxane. SU-8 is particularly suitable because of its chemical barrier properties and its ability to protect the underlying layers from any degrading species that might originate from any overlying elements.

The above-described technique has the advantage that it can avoid the need for an adhesion-promoting interlayer between the parylene layer 7 and the upper gold layer 8. The use of adhesion promoting interlayers made from solution-processible organic polymeric materials can be difficult because of layer structuring issues. For example, there would be the challenge of finding a material that can be deposited via a solvent that does not disrupt the important underlying layers and interfaces, including the interface between the semiconductor layer 5 and the gate dielectric layer 6. In the above-described embodiment of the present invention, the upper gold layer 8 is deposited directly on the parylene layer 7 without any adhesion-promoting interlayer.

With reference to FIG. 4, it is also possible to achieve the patterning of the upper gold layer 8 on the parylene layer 7 by using an organic interlayer 52 and a laser beam of a frequency at which the organic interlayer 52 in the irradiated regions melts and explodes causing mechanical lift-off of the overlying gold layer 8 in those regions.

It has been found that patterning by laser ablation can leave the remaining non-ablated portions 9 of the gold layer 8 with up-bent edges 54, which are found to be undesirable because they can cause high electric fields, dielectric breakdown problems and shorts between a gate line and an overlying pixel electrode 50, which pixel electrode is connected by an interlayer connect (via) (not shown) to the drain electrode of the TFT associated with that pixel electrode 50. One solution is to select a thickness for the overlying layer 10 that is sufficient to prevent such problems. The inventors have found that an overlying layer thickness of at least about 2 microns, more particularly at least about 3 microns, and more particularly about 3.5 microns is effective for substantially eliminating the risk of such problems.

From the point of view of increasing the effectiveness of the above-mentioned technique for large-area gold elements, it is advantageous to pattern any large area gold elements so as to define extra sites for the above-mentioned intertwisting of the polymer chains of the parylene layer 7 and polymer chains of the SU-8 epoxy resin layer 10. One example of this is shown in FIG. 2, in which a large-area gold element 20 is patterned so as to define through holes 22 by which the overlying SU-8 epoxy resin layer (not shown) can contact the underlying parylene layer 7 to provide sites within the metal element for the above-mentioned intertwisting of the polymer chains of the parylene layer 7 and polymer chains of the overlying SU-8 epoxy resin layer. Another example is to pattern a large-area element into an array of parallel sub-elements, wherein the locations between the sub-elements provide extra sites for the above-mentioned intertwisting of the polymer chains of the parylene layer 7 and polymer chains of the SU-8 epoxy resin layer 10. It is preferred that the density of gold coverage is no more than 90% for any 1 mm×1 mm unit area.

The above-described technique is of particular use in TFT devices of the kind described above including a relatively thin gate dielectric layer 6. In more detail, this technique of improving the retention of gate lines on an underlying organic layer makes it possible to avoid the use of more reactive metals such as copper or aluminium for the gate lines 9, which more reactive metals can be preferred from the point of view of good adhesion with the underlying organic layer, but have been found to be relatively prone to electrochemical decomposition within the device causing breaks in the gate lines and consequent device failures.

We have chosen the example of a TFT array of an electrophoretic display device for the description of a technique in accordance with an embodiment of the present invention, but the technique is also of use in improving the retention of a metal element on an underlying organic layer in other kinds of electronic devices.

Furthermore, we have chosen the example of gold on a parylene material to describe a technique according to an embodiment of the present invention, but the technique is equally applicable, for example, to improving the retention of elements of other noble metals, such as platinum, palladium and iridium on underlying layers of parylene or other organic materials; and to improving the retention of non-metallic conductive elements whose adhesion to an underlying layer is poor.

Furthermore, we have chosen the example of a gate line on an underlying organic layer in a top-gate TFT structure to describe a technique according to an embodiment of the present invention, but the technique is equally applicable, for example, to improving the retention of conductive elements to an underlying organic layer in a bottom-gate structure.

In addition to any modifications explicitly mentioned above, it will be evident to a person skilled in the art that various other modifications of the described embodiment may be made within the scope of the invention.

1. A method comprising: forming a conductive element of an electronic device on a portion of the surface of a first organic layer, applying a second organic layer over said conductive element and said first organic layer, and then treating at least one of the first and second organic layers to increase the strength of adhesion between said first and second organic layers and thereby improve the retention of said conductive element on said first organic layer.

2. A method according to claim 1, wherein said conductive element is a metal element.

3. A method according to claim 2, wherein forming said metal element includes patterning a deposit of metal through the direct absorption of laser energy and evaporation of metal at selected regions of said deposit.

4. A method according to claim 2, wherein said metal is a noble metal element.

5. A method according to claim 4, wherein said noble metal element is gold.

6. A method according to claim 1, wherein the conductive element forms part of a conductive pattern, and wherein the density of coverage of the conductive pattern is no more than 90% for any 1 mm×1 mm unit area.

7. A method according to claim 6, wherein the conductive element forms part of a conductive pattern, and wherein the density of coverage of the conductive pattern is no more than 50% for any 1 mm×1 mm unit area.

8. A method according to claim 1, wherein the second organic layer exhibits better chemical barrier properties than the first organic layer.

9. A method according to claim 1, wherein applying said second organic layer over said conductive element and said first organic layer comprises depositing a solution of an organic material in a solvent onto said conductive element and said first organic layer, wherein said solvent is compatible with said conductive element.

10-15. (canceled)

16. The use of a noble metal for a gate line in an organic thin-film transistor for the purpose of reducing gate-line breaks.

17. The use of a noble metal for a gate line above a solution-processed organic gate dielectric layer having a thickness of no greater than about 300 nm.

18-19. (canceled)
